(19) United States
(12) Patent Application Publication
(10) Pub. No.: US 2025/0197584 A1
(43) Pub. Date: Jun. 19, 2025

(54) CERAMIC PARTICLES IN A BICONTINUOUS PHASE AND METHOD OF PRODUCTION THEREFOR

(71) Applicants: National Research Council of Canada, Ottawa (CA); Xerox Corporation, Norwalk, CT (US)

(72) Inventors: Yujie ZHANG, Ottawa (CA); Thomas LACELLE, Ottawa (CA); Mohammad RAFIEE, Ottawa (CA); Chantal PAQUET, Ottawa (CA); Derek ARANGUREN VAN EGMOND, Ottawa (CA); Silvio Elton KRUGER, Brossard (CA); Claudie ROY, Montreal (CA); Sarah VELLA, Milton (CA)

(21) Appl. No.: 18/848,995

(22) PCT Filed: Mar. 16, 2023
(86) PCT No.: PCT/CA2023/050339

§ 371 Date: Sep. 20, 2024

Related U.S. Application Data
(60) Provisional application No. 63/322,338, filed on Mar. 22, 2022.

(51) Int. Cl. C08J 9/28; C08J 9/00; C08J 9/40; C08K 3/22; H10N 30/092; H10N 30/85

(52) U.S. Cl. CPC C08J 9/283; C08J 9/0066; C08J 9/405; C08K 3/22; H10N 30/092; H10N 30/852; C08J 2201/0504; C08J 2205/028; C08J 2329/04; C08K 2003/2296

(57) ABSTRACT

An extrudable composition includes: an aqueous phase comprising acidic water and piezoelectric ceramic particles suspended in the water; and, an organic phase having an organic solvent, a curable polymer precursor or both an organic solvent and a curable polymer precursor. The composition is 3-D printable to form a self-supporting structure and may be infiltrated with an organic polymer material or cured so that the curable polymer precursor forms an organic polymer material thereby forming a piezoelectric composite having piezoelectric ceramic particles in a co-continuous phase.

### CROSS-REFERENCE TO RELATED APPLICATIONS

This application claims the benefit of U.S. Provisional Application 63/322,338 filed Mar. 22, 2022, the entire contents of which is herein incorporated by reference.

### FIELD

This application relates to piezoelectric compositions having piezoelectric ceramic particles, methods of producing the compositions and their use, particular in piezoelectric sensors and actuators.

### BACKGROUND

Piezoelectric materials have the ability to convert electrical energy to mechanical energy when generating an interrogating acoustic pulse, and conversely, they can convert mechanical energy into electrical energy while detecting the echoes of an acoustic pulse (FIG. 1). These materials are used for a wide range of technological applications that include ultrasound transducers for naval, medical and nondestructive evaluation applications, fuel injectors for diesel engines and energy harvesting from ambient vibrations. The versatility of piezoelectric materials has found widespread applications as sensors, actuators, transducers, and energy harvesters in industries including aerospace, automotive, mining, nuclear, oil and gas, manufacturing and biomedical.

Various processes involving ceramic-based materials (e.g., ceramic sol-gels, microparticles and/or nanoparticles) to fabricate piezoelectric films have been used to fabricate outstanding ultrasonic transducers used to monitor cracks, corrosion, and erosion. Their superior performance combined with low footprint make these transducers of high interest. However, there is an emerging need to manufacture high volumes of embedded sensors to obtain more accurate sensing data. Production methodology of lead zirconate titanate (PZT) ceramics currently used, which entails numerous material layers, is labor and time intensive with low freedom to modify design parameters. Commercial products that provide manufacturing solutions, such as those based on PVDF polymers, do not meet the performance requirements needed for most sensing applications. Therefore, there is a need for ceramic-based materials compatible with additive processes to allow increased design freedom and ease of integration into parts.

3D printing methods, such as extrusion and direct ink writing, are well-suited to transition lengthy ceramic-based material assembly into an industry-relevant process. 3D printing via direct ink writing (DIW) is an approach that offers the possibility to design and create objects in a variety of shapes and sizes by simple extrusion of paste-like materials (inks) through a nozzle, whereby the object's structure can be controlled by the deposition pattern of the filaments. This approach has been used to fabricate piezoelectric materials using piezoelectric inks made of a mixture of piezoceramic particles and a polymer matrix.

There are several drawbacks of conventional PZT composites. Conventional PZT composites lack morphology control. Because PZT particles are not homogenously dispersed, the PZT particles often form isolated agglomerates within a polymer matrix. This morphology limits load transfer between PZT particles, resulting in less effective piezoelectric properties (i.e., lower piezoelectric coefficient d₃₃ values). In addition, in the cases of conventional PZT composites, load often gets dampened in the matrix material which can decrease the overall d₃₃ values. Ideal piezoelectric materials have PZT ceramic particles forming a percolated network for efficient load transfer. However, to make sure conventional PZT composites are printable and at the same time provide desired physical and mechanical properties (e.g., toughness, mechanical strength, and adhesion), a certain amount of polymer is required in the formulation, which also limit the overall piezoelectric performance. Thus, a challenge to using polymer-ceramic composites with additive manufacturing is the highly coupled relationship between morphology and piezoelectric response. A number of requirements must be met to render polymer-ceramic composites 3D printable and these requirements tend to influence the morphology, composition, and compliance of the composite which ultimately has a strong impact on the piezoelectric response. Therefore, the ink formulation, the approach to printing, and the method of processing are all important to achieving high performing piezoelectric sensors.

There remains a need for ceramic-based compositions that are printable and that provide improved piezoelectric properties together with desired physical and mechanical properties.

### SUMMARY

An extrudable composition comprises: an aqueous phase comprising acidic water and piezoelectric ceramic particles suspended in the water; and, an organic phase comprising an organic solvent, a curable polymer precursor or both an organic solvent and a curable polymer precursor.

A piezoelectric composite comprises piezoelectric ceramic particles in a co-continuous phase with an organic polymeric material, the piezoelectric composite produced by curing the composition described above.

A method for producing a piezoelectric composite comprising piezoelectric ceramic particles in a co-continuous phase with an organic polymeric material is provided in which the method comprises: providing the composition as defined above wherein the organic phase comprises the organic solvent, allowing the organic solvent to evaporate to form a porous ceramic structure and infiltrating the porous ceramic structure with the organic polymeric material to form the piezoelectric composite; or, providing the composition as defined above wherein the organic phase comprises the curable polymer precursor, curing the curable polymer precursor to form the organic polymeric material thereby forming the piezoelectric composite.

The composition is a 3D extrusion printable (i.e., shear thinning and self-supporting rheology) emulsion based on piezoelectric ceramic particles (e.g., lead zirconate titanate (PZT) ceramic particles), which lead to a co-continuous morphology with densely packed ceramic particles in one phase and polymer in the other phase once printed, cured and/or annealed. The co-continuous morphology allows better connections and load transfers between piezoelectric ceramic particles, resulting in better piezoelectric performance at a given volume (or weight) fraction of ceramic particles. At the same time, the polymer phase provides better mechanical properties compared with conventional piezoelectric ceramic composites. In some embodiments, the co-continuous morphology is a bicontinuous morphology.

The co-continuous morphology can be achieved via emulsion templating, which is a widely used approach due to its applicability for various ceramic powders and chemistries and the possibility to tune pore morphology and degree of porosities in a relatively easy fashion. In an embodiment, the composition formulation comprises two phases: an aqueous phase comprising acidic water and piezoelectric ceramic particles as well as possibly one or more of nanocarbon particles, a water-soluble polymer binder, a surfactant and a sol-gel; and, an organic phase comprising a solvent, a curable polymer precursor or both a solvent and a curable polymer precursor. The composition is an emulsion that is extrudable and self-supporting. Importantly, no or fewer cracks are observed once the composition is printed and cured.

The co-continuous morphology can be finely controlled via tuning the formulation (e.g., varying ceramic particle concentration, choosing different types of curable polymer precursor, etc.), which can lead to ceramic particle-based piezoelectric materials with a wide range of d₃₃ values. Ceramic particle-based materials can be produced with various shapes. In addition, the presence of a polymer phase can be used to better match impedance values with adjacent materials, thus enabling the piezoelectric composite material to better target a particular application by selecting appropriate curable polymer precursors.

Further features will be described or will become apparent in the course of the following detailed description. It should be understood that each feature described herein may be utilized in any combination with any one or more of the other described features, and that each feature does not necessarily rely on the presence of another feature except where evident to one of skill in the art.

### BRIEF DESCRIPTION OF THE DRAWINGS

For clearer understanding, preferred embodiments will now be described in detail by way of example, with reference to the accompanying drawings, in which:

FIG. 1 depicts: A) SEM image of PZT ceramic particles in a bicontinuous morphology in a piezoelectric sample formed from an emulsion paste formulation; B) a schematic diagram showing the connectivity of ceramic particles (black circles) with polymer occlusions (grey area) in the bicontinuous morphology; C) SEM image of a piezoelectric sample formed from a composite paste formulation of PZT ceramic particles in a polymer matrix; and, D) a schematic diagram showing the morphology of the piezoelectric sample formed from the composite paste formulation.

FIG. 2 depicts a graph of d₃₃ (pC/N) vs. lead zirconate titanate (PZT) loading (vol %) for piezoelectric samples formed from emulsion paste formulations of PZT ceramic particles, where the PZT ceramic particles are in a bicontinuous phase with NOA 89H adhesive.

FIG. 3 depicts SEM images depicting morphology differences between the piezoelectric samples in FIG. 2.

FIG. 4 depicts a graph of d₃₃ (pC/N) vs. lead zirconate titanate (PZT) loading (vol %) for piezoelectric samples formed from emulsion paste formulations of PZT ceramic particles, where the PZT ceramic particles are in a bicontinuous phase with NEA 121 adhesive.

### DETAILED DESCRIPTION

The extrudable composition comprises: an aqueous phase comprising acidic water and piezoelectric ceramic particles suspended in the water; and, an organic phase comprising an organic solvent, a curable polymer precursor or both an organic solvent and a curable polymer precursor.

The composition preferably has a viscosity of 1,000 cP to 200,000 cP, more preferably 5,000 cP to 100,000 cP, as measured when shear rates are in a range of 5-10 s⁻¹. The viscosity was evaluated using a coaxial cylinder rheometer by measurements of torque at controlled shear rates to yield viscosity profiling, shear thinning response, and yield stress. The composition forms a self-supporting structure on printing, the self-supporting structure having a yield stress of 100 Pa or greater. Yield stress is estimated as the inflection point in the graph of shear stress vs. shear rate. Shear stress is calculated as the product of Viscosity×Shear Rate (Units: Pa·s×s⁻¹═Pa).

### Aqueous Phase:

The aqueous phase comprises water. The water is acidic having a pH of less than 7. Preferably, the pH is in a range of 2-5. The water is preferably present in the composition in an amount in a range of 5-25 wt %, based on total weight of the paste, more preferably 7-20 wt %, yet more preferably 7-17 wt %.

The aqueous phase also comprises piezoelectric ceramic particles. The ceramic particles may be suspended or otherwise dispersed in the water. The ceramic particles may be made of lead zirconate titanate (PZT) or other ceramic materials such as those with perovskite structures which include BaTiO₃, KNbO₃, ZnO, BiFO₃ and Bi₄Ti₃O₁₂. A combination of these may be used. The ceramic particles are preferably present in the paste in an amount in a range of 80 wt % or less, based on the total weight of the paste, more preferably 70 wt % or less, yet more preferably 65 wt % or less. The ceramic particles may be present in the paste in an amount in a range of 35-80 wt %, more preferably 35-75 wt %, yet more preferably 50-75 wt % or 35-65 wt %. The ceramic particles preferably have an average particle diameter of 100 nm or greater, more preferably 500 nm or greater. The ceramic particles preferably have an average particle diameter of 40 μm or less, more preferably 10 μm or less. The ceramic particles are preferably crystalline.

The aqueous phase my further comprise a sol-gel of ceramic particles. The sol-gel may be initially prepared by using standard acid-catalyzed aqueous based sol-gel synthesis techniques. The sol-gel preferably comprises ceramic nanoparticles, especially lead zirconate titanate (PZT), BaTiO₃, KNbO₃, ZnO, BiFO₃, Bi₄Ti₃O₁₂ or any combination thereof, suspended in a gel. The ceramic particles are generally formed during the preparation of the sol-gel from ceramic precursors, for example by a reaction between a metal salt and a suitable oxide. For example, BaTiO₃ particles can be formed through the reaction of barium acetate and titanium (IV) isopropoxide during gelation of the sol-gel. The ceramic particles formed in this way are generally amorphous and have an average particle diameter of under 100 nm. The sol-gel is preferably present in the paste in an amount of 1-10 wt %, based on total weight of the paste, more preferably 2-7 wt %. The sol-gels are made from ceramic precursors, which provides a stiff material matrix helping to increase the piezoelectric response of the material. Sol-gel nanoparticles are particularly useful for the tuning of the rheological properties of the paste to ensure that the paste forms a uniform suspension and is capable of being deposited while also being able to support itself during printing.

The aqueous phase my further comprise nanocarbon particles. Nanocarbon particles include, for example, graphite, graphene, graphene oxide (GO), reduced graphene oxide (r-GO), carbon nanotubes (e.g., single-walled carbon nanotubes, multi-walled carbon nanotubes), fullerenes and the like. Nanocarbon particles improve electrical characteristics of the ceramic material. The nanocarbon particles are preferably present in the paste in an amount in a range of 0.1-2 wt % based on total weight of the paste, more preferably 0.05-1 wt %.

The aqueous phase may further comprise a water-soluble polymer binder. The water-soluble polymer binder is preferably a water-soluble organic polymer binder. The water-soluble polymer binder is more preferably polyvinylpyrrolidone (PVP), polyacrylic acid (PAA), polyvinyl alcohol (PVA), polyethyleneglycol (PEG) or any combination thereof. The paste preferably comprises 0.05-5 wt %, more preferably 2-5 wt %, of the water-soluble polymer binder, based on the total weight of the paste. In addition to being a binder, the polymer can act as a rheology modifier and/or a stabilizer. The water-soluble polymer binder is particularly useful for the tuning of the rheological properties of the paste to ensure that the paste forms a uniform suspension and is capable of being deposited while also being able to support itself during printing. Further, the water-soluble polymer binder also serves to minimize cracks, delamination between printed layers and enables a high loading of the ceramic particles in the paste.

The aqueous phase my further comprise a surfactant. The surfactant is preferably an anionic surfactant that stabilizes cationic metal ions in an aqueous environment. Anionic surfactants contain anionic functional groups, such as sulfate, sulfonate, phosphate and carboxylates. Some examples include alkyl sulfates include ammonium lauryl sulfate, sodium lauryl sulfate (sodium dodecyl sulfate, SLS, or SDS), and the related alkyl-ether sulfates sodium laureth sulfate (sodium lauryl ether sulfate or SLES), and sodium myreth sulfate. The Tween™ series surfactants are particularly preferred, such as polysorbate 20 (polyoxyethylene (20) sorbitan monolaurate), polysorbate 40 (polyoxyethylene (20) sorbitan monopalmitate), polysorbate 60 (polyoxyethylene (20) sorbitan monostearate), polysorbate 80 (polyoxyethylene (20) sorbitan monooleate). The surfactant is preferably present in the paste in an amount in a range of 0.1-2 wt % based on total weight of the paste, more preferably 0.5-1 wt %.

### Organic Phase:

In some embodiments, the organic phase comprises an organic solvent. The organic solvent should be sufficiently hydrophobic to form a separate phase from the aqueous phase. The organic solvent may comprise a mixture of different organic solvents. Some examples of organic solvents include liquid alkanes (e.g., pentanes, hexanes, heptanes, octanes, nonanes, decanes, undecanes, dodecanes and the like). Alkanes are preferred, especially octane. The organic solvent is preferably present in the paste in an amount in a range of 15-55 wt % based on total weight of the paste, more preferably 20-50 wt %. The organic solvent is sacrificial. Once the emulsion is printed, the organic solvent is allowed to evaporate thereby forming a porous ceramic structure. Thus, post printing and processing, the print is a porous ceramic structure. The porous ceramic structure is then infiltrated with an organic polymeric material to fill the pores to produce a composite with a co-continuous phase.

In some embodiments, the organic phase comprises a curable polymer precursor. The curable polymer precursor may be one or more monomers or a resin. The curable polymer precursor is curable to produce an organic polymeric material. Curing may be performed by any suitable method, for example thermal or photonic curing, in the presence or absence of an initiator depending on the polymer precursors involved. The organic polymer material preferably comprises acrylates (e.g., 2-ethylhexyl acrylate (EHA), 1,6-hexanediol diacrylate (HDA)), methacrylate-based resins, urethanes, mercapto ester-based polymers, ethers (e.g., 4-butanediol divinyl ether (BDE)), pentaerythritols (e.g., pentaerythritol tetra (3-mercaptopropionate) (PETMP), styrenes, vinylics, epoxy-based resins, thiol-based resins, or mixtures thereof. A particularly useful class of curable polymer precursors are thiol-ene systems comprising thiol and vinyl precursors containing an initiator to permit thermal curing. The curable polymer precursor is preferably present in the paste in an amount in a range of 15-55 wt % based on total weight of the paste, more preferably 15-40 wt %. After printing the emulsion and drying the printed emulsion to remove the water, thermally or photonically treating the dried emulsion initiates curing of the curable polymer precursor to form an organic polymeric material thereby producing a composite with a co-continuous phase.

The organic phase my further comprise the nanocarbon particles described above, instead of or in addition to the aqueous phase comprising the nanocarbon particles. Form Factors:

The composition preferably has a form factor suitable for additive manufacturing. Suitable form factors of the compositions that may be processed by extrusion include composite filaments, composite pellets, composite powders, composite pastes, or any combination thereof.

Composite filaments compatible with fused filament fabrication may be formed. Although composite filaments may be an advantageous and particularly versatile form factor, it is to be realized that composite pellets may also be produced by producing larger extrudates, which may then be cut, shredded, pulverized, or the like to afford composite pellets of a specified size and geometry or composite powders having even smaller dimensions and a wide distribution of particle sizes. Other than having a different shape, the microscopic morphology of the composite pellets may be similar to that of composite filaments. Like composite filaments, composite pellets and composite powders may be subsequently processed into printed parts having piezoelectric properties under suitable additive manufacturing conditions. “Filaments” are to be distinguished from “fibers” on the basis that filaments comprise a single elongate form factor, whereas fibers comprise multiple filaments twisted together (bundled) to form a fine thread or wire in which the individual filaments remain identifiable. As such, filaments have smaller diameters than do fiber bundles formed therefrom, assuming no filament compression takes place when forming a fiber bundle. Filaments obtained by solution electrospinning or melt electrospinning are usually up to about 100 μm in diameter, which is too small to be effectively printed using fused filament fabrication. The composite filaments obtained herein, in contrast, may be about 0.5 mm or more in size and dimensioned for compatibility with a particular printing system for fused filament fabrication.

Extrudable composite pastes are particularly preferred. As used herein, the term “paste” refers to a composition that is at least partially fluid at a temperature of interest. The term “paste” does not necessarily imply an adhesive function of any type. Moreover, the terms “paste” and “ink” may be used interchangeably with one another in the disclosure herein with respect to direct writing additive manufacturing processes. Unlike composite filaments and composite pellets discussed in brief above, extrudable composite pastes may comprise at least one solvent to facilitate extrusion. The piezoelectric ceramic particles may be suspended in an aqueous phase whereby the paste is an emulsion of the aqueous phase and an organic phase. The organic phase may comprise an organic solvent and/or curable polymer precursors, whereby a co-continuous morphology occurs upon formulation or printing of the extrudable composite paste.

Pastes may be deposited by any suitable method, for example 2-D printing (e.g., screen printing), 3-D printing (e.g., material extrusion or direct-ink-writing (DIW)), stereolithography, powder fusion, vat photopolymerization, binder bonding and the like. The paste is best suited for 3-D printing. DIW is preferred. The paste may be free-standing after printing or may be deposited on any suitable substrate, for example a ceramic, a glass, a metal and the like. The paste is advantageously extrudable, shear thinning, self-supporting or any combination thereof. It is particularly advantageous that the paste is all of advantageously extrudable, shear thinning and self-supporting.

The extrudable pastes are emulsions. The emulsions have an aqueous phase, where ceramic particles reside, and an oil phase, which comprises either a sacrificial organic solvent or curable polymer precursor. The paste meets the following conditions and is therefore printable:
1. Forms a stable emulsion.
2. Shear thinning to allow the paste to extrude through nozzles with a typical inner diameter of 0.8 mm but could range between 0.2 to 1.6 mm.
3. High yield stress so that the printed structure is self-supportable after printing.

The first condition is met by formulating with the appropriate ratio of water, ceramic particles and solvent or curable polymer precursor, and may be assisted with appropriate amount of water-soluble polymer binder. The second two conditions are met by ensuring the viscosity of the paste is in a range of 1,000 to 200,000 cP, especially 5,000 to 100,000 cP.

### Examples

### Chemicals

Lead zirconate titanate (PZT) particles were purchased from APC International. Graphene oxide was purchased from Graphenea. NOA 83H, NOA 61, NOA 89H and NEA 121 uncured adhesive polymer precursors were purchased from Norland Products. N-octane (OCT) and 2-ethylhexyl acrylate (EHA), polyvinyl alcohol (PVA), pentaerythritol tetra (3-mercaptopropionate) (PETMP), 4-butanediol divinyl ether (BDE) and pyrogallol were purchased from Sigma-Aldrich. 1,6-Hexanediol diacrylate (HDA) was purchased from Alfa Aesar.

### Preparation of Sol-Gels

Sol-gels were prepared by adapting standard acid-catalyzed aqueous based sol-gel synthesis techniques. Unless otherwise mentioned, the sol-gels were used in the formulations as-synthesized. Sol-gels synthesis and further experimental methodology are described in International Patent Application PCT/CA2021/051173 filed Aug. 24, 2021, the entire contents of which is herein incorporated by reference.

To obtain an aqueous BTO sol-gel, 4 g barium acetate was mixed with 11.6 g glacial acetic acid. The mixture was heated to 60° C. until the barium acetate was completely dissolved. In a separate container, 1 g of titanium (IV) isopropoxide was dissolved in 1 g of isopropanol at room temperature (RT). Once the barium acetate solution was cooled to room temperature, it was then poured into titanium (IV) isopropoxide solution. The combined solutions were left to stir for 1 hour and then placed in an ice bath. During vigorous magnetic stirring, 12.76 g of MilliQ water was then poured into the cooled solution, and the solution was left to stir for 1 hour to form the aqueous BTO sol-gel.

To obtain an aqueous sol-gel containing lead, a mixture of particular titanium and zirconate alkoxides (mole ratio of Zr: Ti=52:48) was prepared along with the addition of particular solvents at room temperature. After raising the temperature of the solution to 90° C., a slight stoichiometric excess of lead acetate trihydrate was added and the mixture was allowed to cool back down to room temperature. Once at room temperature, additional solvents including a high boiling point solvent and water were added. The mixture was then left to stir overnight to obtain the aqueous sol-gel containing lead.

To obtain a lead-free aqueous sol-gel (Pb-free aqueous sol-gel), a similar process for making the sol-gel containing lead can be used, but without the addition of lead acetate. Prior to the addition of water, acetylacetone is also added at a concentration of 250 ppm (w/w) to improve the stability of the lead-free aqueous sol-gel.

### Processing of PZT Particles

Commercially purchased crystalline PZT particles were processed prior to use to break down the large cluster of particles into individual particles. 100 g PZT particles were dispersed in 100 ml of ethanol in a beaker. The dispersion of PZT particles was stirred using a magnetic bar, and at the same time sonicated using a probe sonicator 15 with a microtip 6 mm in diameter for 25 minutes at 25 W (amplitude 15). The PZT dispersion was cooled in an ice bath during the mixing and sonication. After sonication, PZT particles were filtered and dried.

### Emulsion Paste Preparation

The emulsion paste formulation includes two phases: an aqueous phase that contains acidic water (deionized water with addition of HCl solution to adjust the pH in a range of 2-5) and processed PZT particles, as well as one or more of a water-soluble polymer binder (e.g., PVA), surfactant (e.g., Tween™ 80), sol-gel, as well as nanocarbon (e.g., graphene oxide (GO)); and an organic phase that may be composed of a solvent and/or a curable polymer precursor. To prepare the emulsion, selected amounts of each component were added to a plastic jar and then mixed in a planetary centrifugal mixer (Thinky™) for 5 mins. For example, 18.6 g processed PZT particles, 6.0 g acidic water, 0.25 g graphene oxide, and 12.0 g NOA 89H were measured in a 100 ml plastic jar and then plenary mixed for 5 mins to achieve a stable emulsion paste. A list of tested formulations is provided in Table 1.

TABLE 1

| | | | | | Sol- | | | | Viscosity at | |
|---|---|---|---|---|---|---|---|---|---|---|
| | PZT | Water | GO | PVA | gel | Surfact. | Oil | | 5 s⁻¹ shear | D₃₃ |
| # | wt % | wt % | wt % | wt % | wt % | wt % | wt % | Oil phase | rate (cP) | (pC/N) |
| 1 | 42.7 | 14.2 | 0 | 0 | 0 | 0 | 43.1 | 100% OCT | 16200 | |
| 2 | 42.7 | 14.2 | 0.06 | 0 | 0 | 0 | 43.1 | 100% OCT | 43700 | |
| 3 | 39.5 | 13.3 | 0 | 0 | 0 | 0 | 47.2 | 100% OCT | 25200 | |
| 4 | 44.0 | 14.6 | 0.13 | 0 | 0 | 0 | 41.3 | 100% OCT | 31800 | |
| 5 | 45.4 | 14.8 | 0.08 | 0 | 0 | 0 | 39.7 | 100% OCT | 60000 | |
| 6 | 44.3 | 14.8 | 0.16 | 0 | 0 | 0 | 40.8 | 100% OCT | 22300 | |
| 7 | 45.3 | 14.8 | 0.08 | 0.15 | 0 | 0 | 39.6 | 100% OCT | 56600 | |
| 8 | 50 | 16.5 | 0.2 | 0 | 0 | 0 | 33.3 | 100% OCT | 26100 | |
| 9 | 45.1 | 14.8 | 0.1 | 0.52 | 0 | 0 | 39.5 | 100% OCT | 84000 | |
| 10 | 36.0 | 12.1 | 0 | 0 | 0 | 0 | 51.9 | EHA/HDA | 25800 | |
| | | | | | | | | (50/50) | | |
| 11 | 42.7 | 14.3 | 0.06 | 0 | 0 | 0 | 43.0 | EHA/HDA | 25200 | |
| | | | | | | | | (50/50) | | |
| 12 | 43.7 | 14.1 | 0.31 | 0 | 0 | 0 | 41.8 | EHA/HDA | 65200 | |
| | | | | | | | | (50/50) | | |
| 13 | 43.5 | 14.1 | 0.35 | 0 | 0 | 0 | 42.1 | EHA/HDA | 45500 | |
| | | | | | | | | (50/50) | | |
| 14 | 42.9 | 14.3 | 0.07 | 0 | 0 | 0 | 42.8 | EHA/HDA | 21100 | |
| | | | | | | | | (50/50) | | |
| | | | | | | | | OCT | | |
| 15 | 43.5 | 14.1 | 0.36 | 0 | 0 | 0 | 42.1 | EHA/HDA | 45300 | |
| | | | | | | | | (50/50) | | |
| 16 | 43.4 | 14.1 | 0.34 | 0 | 0 | 0 | 42.1 | EHA/HDA | 45200 | |
| | | | | | | | | (50/50) | | |
| 17 | 50.6 | 16.3 | 0.40 | 0 | 0 | 0 | 32.7 | EHA/HDA | 35100 | |
| | | | | | | | | (50/50) | | |
| 18 | 50.8 | 16.4 | 0.16 | 0 | 0 | 0 | 32.7 | 100% OCT | 16400 | |
| 19 | 31.5 | 16.2 | 0 | 0 | 3.4 | 0 | 48.9 | EHA/HDA | N/A | |
| | | | | | | | | (50/50) | | |
| 20 | 50.6 | 16.3 | 0.45 | 0 | 0 | 0 | 32.7 | PETMP | 20000 | |
| | | | | | | | | BDE | | |
| | | | | | | | | pyrogallol | | |
| 21 | 55.0 | 14.3 | 0 | 0 | 3.6 | 0 | 27.2 | EHA/HDA | N/A | |
| | | | | | | | | (50/50) | | |
| 22 | 49.5 | 15.8 | 0 | 0 | 0 | 0 | 34.6 | NOA 89H | N/A | |
| 23 | 54.6 | 13.9 | 0.15 | 0 | 0 | 0 | 31.3 | NOA 83H | N/A | |
| 24 | 55.0 | 13.8 | 0.18 | 0 | 0 | 0 | 31.0 | NOA 61 | N/A | |
| 25 | 50.9 | 16.3 | 0 | 0 | 0 | 0 | 32.8 | NOA 89H | 8700 | 9.3 ± 0.62 |
| 26 | 50.8 | 16.4 | 0.15 | 0 | 0 | 0 | 32.7 | NOA 89H | 15800 | 8.2 ± 0.62 |
| 27 | 50.7 | 16.3 | 0.33 | 0 | 0 | 0 | 32.7 | NOA 89H | 20700 | 9.0 ± 1.50 |
| 28 | 50.5 | 16.3 | 0.67 | 0 | 0 | 0 | 32.5 | NOA 89H | 26500 | 16.0 ± 1.85 |
| 29 | 63.5 | 12.2 | 0 | 0 | 0 | 0 | 24.3 | NOA 89H | 77400 | 13.3 ± 3.70 |
| 30 | 50.3 | 16.3 | 1.01 | 0 | 0 | 0 | 32.4 | NOA 89H | 22400 | 9.6 ± 0.65 |
| 31 | 72.4 | 9.2 | 0 | 0 | 0 | 0 | 18.3 | NOA 89H | N/A | 12.8 ± 0.47 |
| 32 | 77.1 | 7.6 | 0 | 0 | 0 | 0 | 15.3 | NOA 89H | Exceeded | 23.0 ± 2.0 |
| | | | | | | | | | viscometer | |
| | | | | | | | | | limit | |
| 33 | 77.1 | 7.7 | 0 | 0 | 0 | 0 | 15.3 | NOA 89H | Exceeded | N/A |
| | | | | | | | | | viscometer | |
| | | | | | | | | | limit | |
| 34 | 50.7 | 16.2 | 0 | 0 | 0 | 0.7 | 32.4 | NOA 89H | N/A | N/A |
| 35 | 55.6 | 8.9 | 0 | 0 | 0 | 0 | 35.5 | NEA 121 | 40600 | 16.5 |
| 36 | 60.6 | 13.1 | 0 | 0 | 0 | 0 | 26.3 | NEA 121 | N/A | 24.0 |
| 37 | 63.5 | 12.2 | 0 | 0 | 0 | 0 | 24.3 | NEA 121 | N/A | 28.8 |
| 38 | 71.8 | 9.4 | 0 | 0 | 0 | 0 | 18.8 | NEA 121 | N/A | 18.7 |
| 39 | 78.4 | 7.2 | 0 | 0 | 0 | 0 | 14.4 | NEA 121 | N/A | 25.0 |

### Printing and Curing

The prepared pastes were placed into 30 ml syringe tubes and the piston was pushed the paste to the end to remove air inside. A tapered nozzle with inner diameter of 1.19 mm was attached to the syringe before being installed in a 3D printer. A commercially available 3D printer (Hyrel™ System 30M, Atlanta, GA) was used to 3D print the samples using Direct Ink Writing. The ceramic pastes were deposited onto a thin film Kapton™ sheet on top of the print bed to build a 3D structure in dimensions of 15×15×3 mm³. Samples were printed with a speed of 10 mm/s and a layer height of 0.95 mm.

After printing, samples were dried at room temperature for 12 hours to prevent crack formation due to water evaporation. The samples, then, were cured at 80° C. for 4 hours. The thin Kapton™ film helps 3D printed samples peel off easily from the bed.

### Poling and d₃₃ Measurements

The samples were placed inside an oil bath and poled under 10 KV at 120° C. for 1 h using a high-voltage power supply (ES60, 10 W negative, Gamma High Voltage Research, Inc.). The samples were then cooled down to room temperature before removing the electric field. Piezoelectric charge coefficient (d₃₃) was measured using APC make d₃₃ meter model S5865.

### Viscosity Measurement and Sample Imaging

The Viscosity of the emulsion paste was measured using a Brookfield RV-DV-III Ultra Rheometer. The dried emulsion pastes, as well as the printed and cured samples were imaged on a Hitachi SU3500 or a Hitachi S-4700 SEM to observe the morphology.

### Results

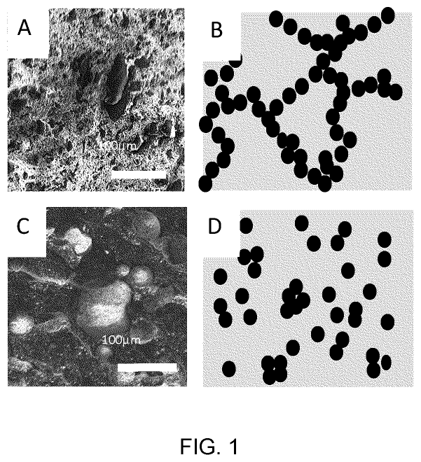

To demonstrate improvements in piezoelectric performance imparted by a bicontinuous ceramic phase, the ‘emulsion’ paste formulations of the present invention were compared to ‘composite’ paste formulations of the prior art. Composite paste formulations were made without water, with everything else being constant. Composite paste formulations have ceramic particles being distributed in a polymer matrix. FIG. 1 illustrates the morphological differences between piezoelectric samples having a bicontinuous ceramic phase formed from an emulsion paste formulation (A and B) and piezoelectric samples formed from a composite paste formulation (C and D).

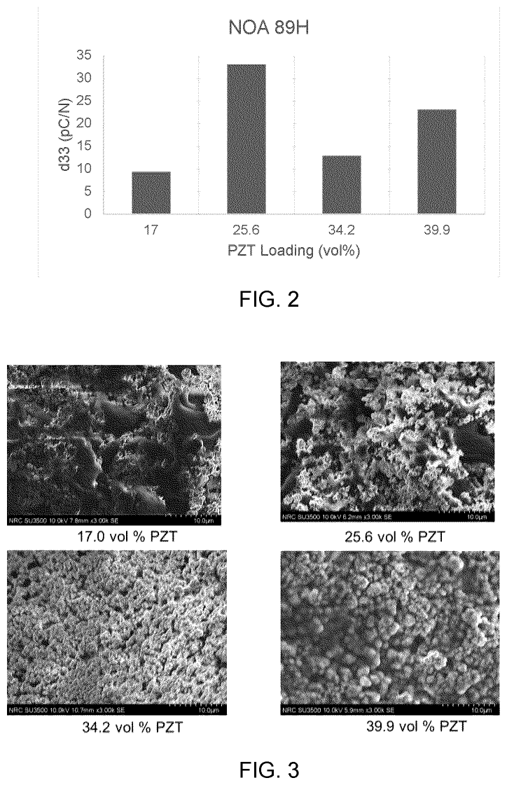

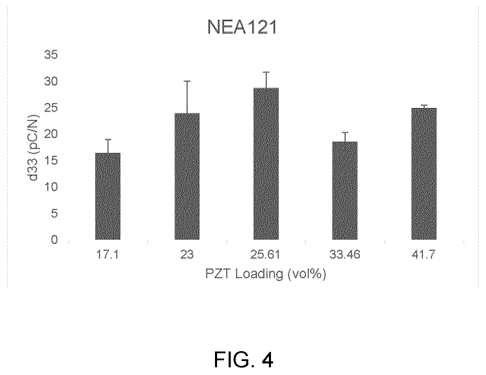

Stable PZT based emulsion pastes can be achieved using the formulation methods described above. With reference to Table 2, PZT based emulsion pastes at various PZT loadings were made using two different oil phases (NOA 89H and NEA 121) and the performance (d₃₃ values) of piezoelectric samples made by direct in writing of the emulsion pastes was determined. It is evident from Table 2 that PZT loading is important to the formation of the bicontinuous phase (FIG. 3), and thus the PZT loading results in different piezoelectric performances (i.e., different d₃₃ values) (FIG. 2 and FIG. 4).

At an appropriate PZT loading (lower than about 26 vol %), a bicontinuous phase can be achieved (see Sample 25 and Sample 29 in Table 2 and FIG. 3), thus higher d₃₃ values can be achieved compared to their composite counterparts (see Sample 25 compared to Sample C25 and Sample 29 compared to Sample C29 in Table 3).

However, above a certain PZT particle loading range, the morphology that resulted was not bicontinuous thus impacting the d₃₃ values (see Sample 31 and Sample 32 in FIG. 3). The less than ideal bicontinuous morphology led to a decrease in d₃₃ values (see 31 and Sample 38 in Table 2), and the overall piezoelectric performances tended towards that of a composite counterpart (compare Sample 31 to Sample C31 in Table 3).

TABLE 2

| Oil | | PZT wt % | | Viscosity at | d₃₃ |
|---|---|---|---|---|---|
| Phase | # | (w_{PZT}/wₜₒₜₐₗ) | PZT vol % | 5 rpm (cp) | (pC/N) |
| NOA | 25 | 50.9 | 17.0 | 8,700 | 9.3 ± 0.60 |
| 89H | 29 | 63.4 | 25.6 | 77,400 | 33.0 ± 0.5 |
| | 31 | 72.4 | 34.2 | NA | 12.8 ± 0.47 |
| | 32 | 77.1 | 39.9 | NA | 23.0 ± 2 |
| NEA 121 | 35 | 55.6 | 17.1 | 40,600 | 16.5 |
| | 36 | 60.6 | 23.3 | NA | 24.0 |
| | 37 | 63.5 | 25.6 | NA | 28.8 |
| | 38 | 71.8 | 33.5 | NA | 18.7 |
| | 39 | 78.4 | 41.7 | NA | 25.0 |

TABLE 3

| | PZT wt % | | Viscosity at | d₃₃ |
|---|---|---|---|---|
| # | (w_{PZT}/wₜₒₜₐₗ) | PZT vol % | 5 rpm (cp) | (pC/N) |
| 25 | 50.9 | 17.0 | 8700 | 9.3 ± 0.6 |
| C25 | 60.9 | 17.0 | NA | 4.5 ± 0 |
| 29 | 63.4 | 25.6 | 77400 | 33.0 ± 0.5 |
| C29 | 72.2 | 25.5 | NA | 15.0 ± 0.5 |
| 31 | 72.4 | 34.2 | NA | 12.8 ± 0.47 |
| C31 | 79.8 | 34.2 | NA | 17.0 ± 0 |

The novel features will become apparent to those of skill in the art upon examination of the description. It should be understood, however, that the scope of the claims should not be limited by the embodiments, but should be given the broadest interpretation consistent with the wording of the claims and the specification as a whole.

1. An extrudable composition comprising:
an aqueous phase comprising acidic water and piezoelectric ceramic particles suspended in the water; and,
an organic phase comprising an organic solvent, a curable polymer precursor or both an organic solvent and a curable polymer precursor.

2. The composition of claim 1, having a form factor selected from the group consisting of a composite filament, a composite pellet, a composite powder, and a composite paste.

3. The composition of claim 2, wherein the form factor is a composite paste.

4. The composition of claim 1, wherein the ceramic particles comprise lead zirconate titanate (PZT) particles.

5. The composition of claim 1, wherein the ceramic particles are present in the paste in an amount of 70 wt % or less, based on total weight of the paste.

6. The composition of claim 1, wherein the ceramic particles are present in the paste in an amount of 65 wt % or less, based on total weight of the paste.

7. The composition of claim 1, wherein the aqueous phase further comprises one or more of a sol-gel of ceramic particles, nanocarbon particles, a water-soluble polymer binder and a surfactant.

8. The composition of claim 1 having a viscosity in a range of 5,000-100,000 cP, as measured at shear rate of 0.08 s⁻¹.

9. The composition of claim 1, wherein the organic phase comprises the organic solvent.

10. The composition of claim 1, wherein the organic phase comprises the curable polymer precursor.

11. A piezoelectric composite comprising piezoelectric ceramic particles in a co-continuous phase with an organic polymeric material, the piezoelectric composite produced by curing the composition as defined claim 1.

12. The material of claim 11, wherein the co-continuous phase is a bicontinuous phase.

13. A method for producing a piezoelectric composite comprising piezoelectric ceramic particles in a co-continuous phase with an organic polymeric material, the method comprising:
a) providing the composition as defined in claim 1 wherein the organic phase comprises the organic solvent,
allowing the organic solvent to evaporate to form a porous ceramic structure and
infiltrating the porous ceramic structure with the organic polymeric material to form the piezoelectric composite; or,
b) providing the composition as defined in any one of claims 1 to 8 wherein the organic phase comprises the curable polymer precursor,
curing the curable polymer precursor to form the organic polymeric material thereby forming the piezoelectric composite.

14. The method of claim 13, wherein the co-continuous phase is a bicontinuous phase.

15. The method of claim 13, wherein the method comprises step b) and the curing is accomplished thermally or photonically in the presence or absence of an initiator.
